(19) United States
(12) Patent Application Publication
(10) Pub. No.: US 2026/0344458 A1
(43) Pub. Date: Oct. 29, 2026

(54) METHOD FOR MANUFACTURING SEMICONDUCTOR PACKAGE, SUBSTRATE MATERIAL FOR SEMICONDUCTOR PACKAGE, AND METHOD FOR MANUFACTURING SUBSTRATE MATERIAL FOR SEMICONDUCTOR PACKAGE

(71) Applicant: Resonac Corporation, Tokyo (JP)

(72) Inventors: Shunsuke OTAKE, Tokyo (JP); Hirokazu NOMA, Tokyo (JP); Masaki TAKAHASHI, Tokyo (JP); Mitsuki NAKATA, Tokyo (JP); Takayo KITAJIMA, Tokyo (JP); Shunsuke TONOUCHI, Tokyo (JP); Kota NAKANISHI, Tokyo (JP)

(21) Appl. No.: 19/479,943

(22) PCT Filed: Jan. 17, 2024
(86) PCT No.: PCT/JP2024/001158

§ 371 Date: Oct. 29, 2025

(51) Int. Cl. H10W 70/05; B32B 5/02

(52) U.S. Cl. CPC H10W 70/096; B32B 5/02; B32B 2262/101; B32B 2307/206; B32B 2457/14

(57) ABSTRACT

A method for manufacturing a semiconductor package, including: cutting out, from a substrate material for semiconductor packages having a first surface and, on a reverse side thereof, a second surface, a plurality of substrates each having the first surface and the second surface; classifying the plurality of cut-out substrates into first substrates that warp toward the first surface side when heated, and second substrates that warp toward the second surface side when heated; and mounting an electronic component including a semiconductor chip on a surface on the first surface side of a wiring substrate including the first substrate, or on a surface on the second surface side of a wiring substrate including the second substrate.

### TECHNICAL FIELD

The present disclosure relates to a method for manufacturing a semiconductor package, a substrate material for semiconductor packages, and a method for manufacturing a substrate material for semiconductor packages.

### BACKGROUND ART

In a semiconductor package, a semiconductor chip may be mounted on a wiring substrate having a core substrate formed from a substrate material and a multilayer wiring layer formed on the core substrate (for example, Patent Literature 1).

### CITATION LIST

### Patent Literature

Patent Literature 1: Japanese Unexamined Patent Publication No. 2017-11156

### SUMMARY OF INVENTION

### Technical Problem

In the manufacturing of a semiconductor package, when a semiconductor chip and a wiring substrate are connected through a heating process such as reflow, warpage may occur due to a difference in the coefficient of thermal expansion between the semiconductor chip and the wiring substrate, etc. To properly connect the semiconductor package to a motherboard, it is desirable that the warpage of the semiconductor package be minimized.

### Solution to Problem

The present disclosure includes the following.
[1]

A method for manufacturing a semiconductor package, comprising:
cutting out, from a substrate material for semiconductor packages having a first surface and, on a reverse side thereof, a second surface, a plurality of substrates each having the first surface and the second surface;
classifying the plurality of cut-out substrates into first substrates that warp toward the first surface side when heated, and second substrates that warp toward the second surface side when heated; and
mounting an electronic component including a semiconductor chip on a surface on the first surface side of a wiring substrate including the first substrate, or on a surface on the second surface side of a wiring substrate including the second substrate.
[2]

A method for manufacturing a semiconductor package, comprising:
cutting out, from a substrate material for semiconductor packages having a first surface and, on a reverse side thereof, a second surface, a plurality of substrates each having the first surface and the second surface;
classifying the plurality of cut-out substrates into first substrates that warp toward the first surface side when heated, and second substrates that warp toward the second surface side when heated; and
mounting an electronic component including a semiconductor chip on a surface on the second surface side of a wiring substrate including the first substrate, or on a surface on the first surface side of a wiring substrate including the second substrate.
[3]

A substrate material for semiconductor packages having a first surface and, on a reverse side thereof, a second surface, wherein
a plurality of sample substrates, which are cut out from the substrate material for semiconductor packages and have the first surface and the second surface in a rectangular shape with a length of 60±1 mm and a width of 60±1 mm, warp toward the first surface side when heated.
[4]

The substrate material for semiconductor packages according to [3], wherein 90% or more of a set of at least ten sample substrates cut out from one sheet of the substrate material for semiconductor packages warp toward the first surface side when heated.
[5]

The substrate material for semiconductor packages according to [3] or [4], wherein the plurality of the sample substrates exhibit a maximum warpage amount of not less than 10 μm and not more than 350 μm when heated to 260 °C.
[6]

The substrate material for semiconductor packages according to any one of [3] to [5], further comprising a label indicating a position of the first surface or the second surface of the substrate material for semiconductor packages.
[7]

The substrate material for semiconductor packages according to any one of [3] to [6], wherein the substrate material for semiconductor packages comprises an insulating substrate formed by heating and pressing a laminate including a plurality of prepregs comprising an inorganic fibrous base material and a thermosetting resin composition impregnated in the inorganic fibrous base material.
[8]

The substrate material for semiconductor packages according to [7], wherein the laminate includes a combination of two or more kinds of the prepregs each comprising a different inorganic fibrous base material, and the two or more kinds of the prepregs are laminated in an order selected such that the plurality of the sample substrates warp toward the first surface side when heated.
[9]

The substrate material for semiconductor packages according to [7] or [8], wherein the laminate includes a combination of two or more kinds of the prepregs each comprising a different thermosetting resin composition, and the two or more kinds of the prepregs are laminated in an order selected such that the plurality of the sample substrates warp toward the first surface side when heated.
[10]

The substrate material for semiconductor packages according to any one of [7] to [9], wherein
the insulating substrate is formed by heating and pressing the laminate under heating conditions in which an amount of heat applied to the laminate from one surface side of the laminate and an amount of heat applied to the laminate from the other surface side of the laminate are different, and
the heating conditions are determined such that the plurality of the sample substrates warp toward the first surface side when heated.
[11]

An accommodated body comprising:
the substrate material for semiconductor packages according to any one of [3] to [10]; and
a container accommodating the substrate material for semiconductor packages and having a label indicating a position of the first surface or the second surface of the substrate material for semiconductor packages.
[12]

A method for manufacturing the substrate material for semiconductor packages according to [7], comprising: forming an insulating substrate by heating and pressing a laminate including a plurality of prepregs comprising an inorganic fibrous base material and a thermosetting resin composition impregnated in the inorganic fibrous base material.
[13]

The method according to [12], wherein the laminate includes a combination of two or more kinds of the prepregs each comprising a different inorganic fibrous base material, and the two or more kinds of the prepregs are laminated in an order selected such that the plurality of the sample substrates warp toward the first surface side when heated.
[14]

The method according to [12] or [13], wherein the laminate includes a combination of two or more kinds of the prepregs each comprising a different thermosetting resin composition, and the two or more kinds of the prepregs are laminated in an order selected such that the plurality of the sample substrates warp toward the first surface side when heated.
[15]

The method according to any one of [12] to [14], wherein the molded body is formed by heating and pressing the laminate under heating conditions in which an amount of heat applied to the laminate from
one surface side of the laminate and an amount of heat applied to the laminate from the other surface side of the laminate are different, and
the heating conditions are determined such that the plurality of the sample substrates warp toward the first surface side when heated.

### Advantageous Effects of Invention

Even when a substrate warps when heated, warpage in a semiconductor package can be reduced.

### BRIEF DESCRIPTION OF DRAWINGS

FIG. 1 is a cross-sectional view showing an example of a substrate material.

FIG. 2 is a schematic diagram showing a method for evaluating warpage of a substrate cut out from a substrate material.

FIG. 3 is a schematic diagram showing a method for evaluating warpage of a substrate cut out from a substrate material.

FIG. 4 is a schematic diagram showing a method for evaluating warpage of a substrate cut out from a substrate material.

FIG. 5 is a schematic diagram showing a method for evaluating warpage of a substrate cut out from a substrate material.

FIG. 6 is a cross-sectional view showing an example of a prepreg.

FIG. 7 is a cross-sectional view showing an example of a method for manufacturing a substrate material.

FIG. 8 is a cross-sectional view showing an example of a semiconductor package.

### DESCRIPTION OF EMBODIMENTS

The present invention is not limited to the following examples. In the present specification, the “thickness direction” means a direction perpendicular to the two principal surfaces having the largest area among the surfaces of a sheet-like material.

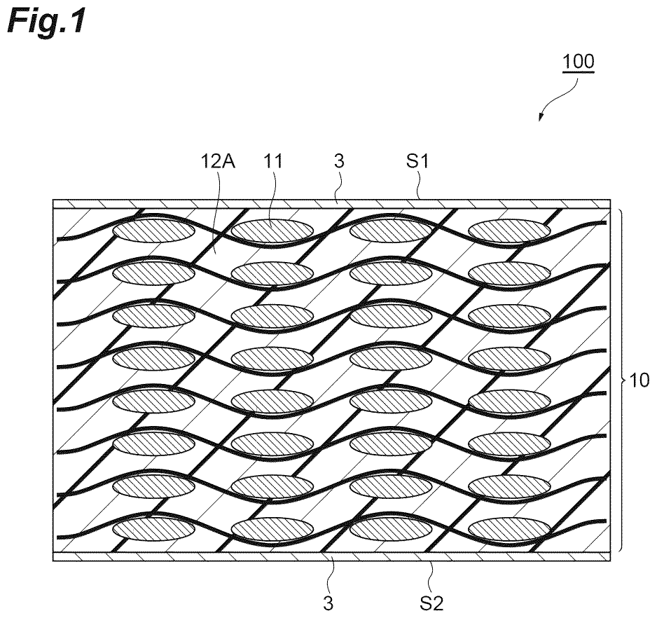

FIG. 1 is a cross-sectional view showing an example of a substrate material. A substrate material 100 shown in FIG. 1 is a sheet-like material having a first surface S1 and a second surface S2 on the reverse side thereof. The substrate material 100 is mainly composed of an insulating substrate 10 and metal foils 3 provided on both surfaces of the insulating substrate 10. The insulating substrate 10 includes an insulating resin layer 12A, which is a cured thermosetting resin composition, and a plurality of inorganic fibrous base materials 11 arranged within the insulating resin layer 12A. The plurality of inorganic fibrous base materials 11 are laminated in the thickness direction of the insulating substrate 10.

Individual substrates cut out from the substrate material 100 are used to form a wiring substrate for mounting a semiconductor package. For example, a wiring substrate for a semiconductor package having fine wiring can be manufactured by using the metal foil 3 of the substrate material 100, or by forming wiring on the insulating substrate 10 after removing the metal foil 3. A substrate cut out from the substrate material 100 may be used as a core material for forming a wiring substrate for a semiconductor package.

The width of the substrate material 100 may be 200 to 2650 mm. The thickness of the substrate material 100 may be 200 to 2000 μm.

The dielectric constant at 10 GHz of the insulating resin layer 12A, which is a cured thermosetting resin composition, may be 3.0 or less, or 2.8 or less. The dielectric loss tangent at 10 GHz of the insulating resin layer 12A may be 0.005 or less. The dielectric constant can be measured using a test piece of a cured product of the thermosetting resin composition with a length of 60 mm, a width of 2 mm, and a thickness of 300 μm. The test piece may be vacuum-dried at 30 °C for 6 hours before measurement. The dielectric loss tangent can be calculated from the resonant frequency and the unloaded Q factor, both obtained at 10 GHz. The measurement apparatus may include a vector network analyzer E8364B manufactured by Keysight Technologies, CP531 (10 GHz resonator) and CPMAV2 (program) manufactured by Kanto Electronic Application and Development Inc. The measurement temperature may be 25 °C.

The glass transition temperature of the insulating resin layer 12A, which is a cured thermosetting resin composition, may be 120 °C or higher, or 140 °C or higher. The glass transition temperature of the insulating resin layer 12A may be 240 °C or lower, or 220 °C or lower.

A substrate cut out from the substrate material 100, having the first surface S1 and the second surface S2, may slightly warp toward the first surface S1 side or the second surface S2 side when heated. In the case of a substrate material manufactured without considering the direction of warpage, a plurality of substrates cut out from one sheet of the substrate material usually includes both those that warp toward the first surface S1 side when heated and those that warp toward the second surface S2 side when heated, due to various factors attributable to variations in materials and processes, and the like. Therefore, it is generally difficult to predict which surface an individual substrate will warp toward.

Therefore, the plurality of cut-out substrates may be classified into first substrates that warp toward the first surface S1 side when heated, and second substrates that warp toward the second surface S2 side when heated. On that basis, an electronic component including a semiconductor chip may be mounted on a surface of the wiring substrate determined in consideration of the warpage direction of each substrate. When mounting an electronic component including a semiconductor chip on a wiring substrate including a substrate whose warpage direction is known in advance, warpage in the semiconductor package may be reduced by appropriately selecting the combination of the orientation of the wiring substrate and the semiconductor chip such that the warpage directions cancel each other out. For example, the semiconductor chip and the substrate may be combined such that their warpage directions when heated are opposite to each other. The electronic component may be selectively mounted on a surface on the first surface S1 side of a wiring substrate including the first substrate, or on a surface on the second surface S2 side of a wiring substrate including the second substrate. Alternatively, the electronic component may be selectively mounted on a surface on the second surface S2 side of a wiring substrate including the first substrate, or on a surface on the first surface S1 side of a wiring substrate including the second substrate.

To classify the plurality of substrates into the first substrate and the second substrate, the warpage direction of each substrate can be evaluated by using each substrate as a sample substrate in a method for evaluating the warpage direction of a sample substrate, which will be described later.

Instead of classifying the plurality of cut-out substrates based on the warpage direction as described above, a substrate material whose warpage direction upon heating is intentionally controlled may be prepared. For example, a substrate material 100 may be prepared, such that, when heated, a plurality of the sample substrates having a rectangular first surface S1 and second surface S2 with a length of 60±1 mm and a width of 60±1 mm, which are cut out from the substrate material 100, warp toward the first surface S1 side when heated. Here, of the two principal surfaces of the substrate material 100, the surface on the side toward which the plurality of the sample substrates 20 warp can be regarded as the first surface S1 of the substrate material 100.

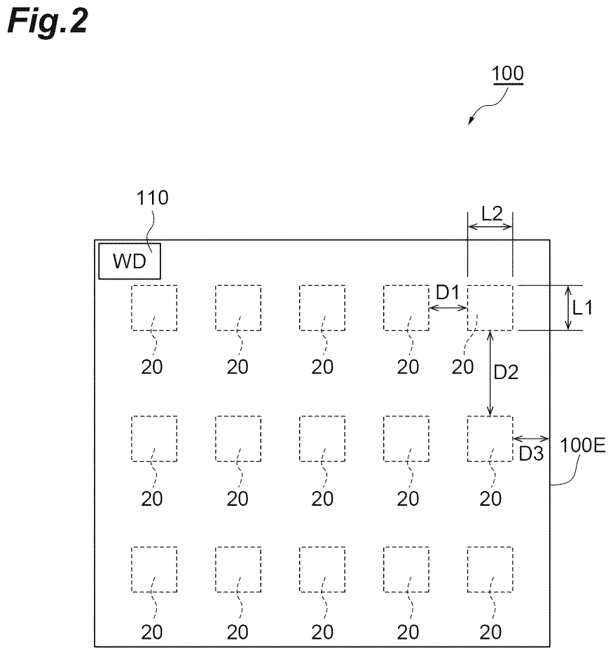

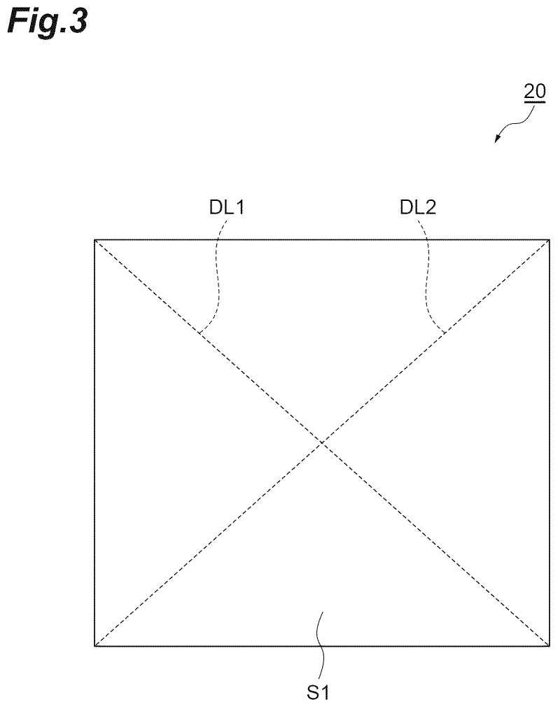

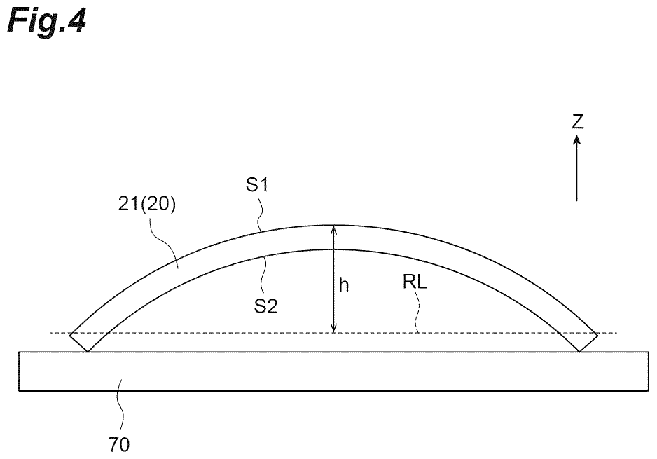

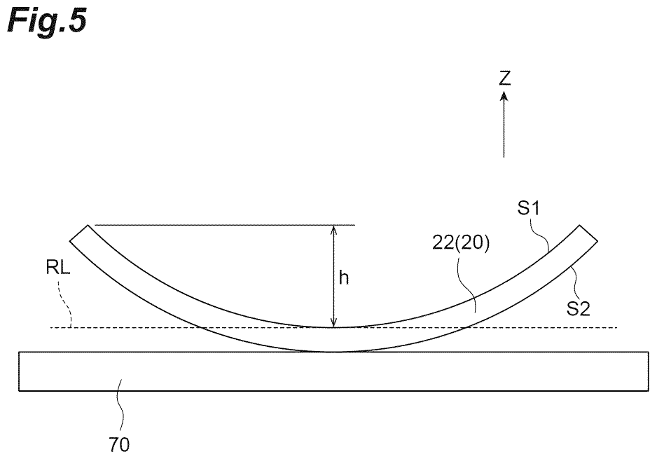

FIG. 2, FIG. 3, FIG. 4, and FIG. 5 schematically show a method for evaluating the warpage direction of a sample substrate cut out from a substrate material. FIG. 2 is a plan view showing the substrate material, and FIG. 3 is a plan view showing a sample substrate (or a substrate). From one sheet of the substrate material 100, portions of a plurality of regions spaced apart from each other by a predetermined distance D1 or D2 are cut out as a plurality of the sample substrates 20. The first surface S1 of the plurality of the sample substrates 20 has a rectangular shape with a vertical length L1 of 60±1 mm and a horizontal length L2 of 60±1 mm. The second surface S2 of the sample substrate 20 also has a rectangular shape similar to the first surface S1. The distances D1, D2 between the regions cut out as the sample substrates 20 may be a minimum of 0.5 mm. The distance D3 between the region cut out as the sample substrate 20 and the end face 100E of the substrate material 100 may be a minimum of 20 mm. When the substrate material 100 has the metal foil 3, the warpage direction is usually evaluated for the sample substrate in a state of having the metal foil 3.

FIG. 4 and FIG. 5 are schematic diagrams showing a sample substrate heated on a stage. The stage may be, for example, a glass plate. The sample substrate is heated by heaters provided below the stage and above the sample substrate. FIG. 4 and FIG. 5 show a cross-section along one of the two diagonal lines of the rectangular first surface S1. FIG. 4 is an example of a first substrate 21 that warps toward the first surface S1 side when heated. FIG. 5 is an example of a second substrate 22 that warps toward the second surface S2 side when heated. The direction of warpage of the sample substrate 20 due to heating is measured by a method including: placing the sample substrate 20 on a horizontal surface of a stage 70 in an orientation where the second surface S2 is in contact with the stage 70; raising the temperature of the surface of the sample substrate 20 from 30 °C to 260 °C, and then lowering it to 40 °C; and measuring the relative height in the vertical direction Z at each position within the first surface S1 when the temperature of the surface of the sample substrate 20 has risen to 260 °C. The temperature of the surface of the sample substrate 20 is measured by a thermocouple. In the portion along each of the two diagonal lines DL1, DL2 of the first surface S1, a difference h between the height of the relatively highest position and the height of the relatively lowest position is obtained. Of the two diagonal lines DL1, DL2, on the diagonal line where the difference h is larger, when the center of the diagonal line is higher than both ends of the diagonal line as illustrated in FIG. 4, the sample substrate 20 is determined to be the first substrate 21, and when the center of the diagonal line is lower than both ends of the diagonal line as illustrated in FIG. 5, the sample substrate 20 is determined to be the second substrate 22.

Most of the plurality of the sample substrates 20 cut out from one sheet of the substrate material 100 may be the first substrates 21 that warp toward the first surface S1 side when heated. For example, 90% or more, 95% or more, or substantially all of 10 or more, or 10 or more and 20 or less, of the sample substrates 20 cut out from one sheet of the substrate material 100 may be the first substrates 21 that warp toward the first surface side when heated.

The plurality of the sample substrates cut out from one sheet of the substrate material 100 may exhibit a maximum warpage amount of not less than 10 μm and not more than 350 μm when heated to 260 °C. The warpage amount can also be measured by the above-described method for measuring the warpage direction. The warpage amount when the substrate material is heated to 260 °C is the difference between the height of the relatively highest position and the height of the relatively lowest position over the entire first surface S1. The warpage amount exhibited by the plurality of the sample substrates cut out from one sheet of the substrate material 100 may be 10 μm or more, or 20 μm or more, and may be 300 μm or less, or 350 μm or less. 90% or more, 95% or more, or substantially all of 10 or more, or 10 or more and 20 or less, of the sample substrates 20 cut out from one sheet of the substrate material 100 may exhibit a warpage amount in the above range when heated. Usually, from the viewpoint of suppressing warpage of a semiconductor package, a substrate that substantially does not warp upon heating is desired, but even for a substrate that exhibits a certain degree of warpage, a semiconductor package with suppressed warpage can be easily provided by appropriately selecting the combination with a semiconductor chip, etc., based on the warpage direction.

The substrate material 100 from which a substrate that warps toward the first surface S1 side is cut out may have a label 110 indicating the position of the surface on the side to which the substrate cut out from the substrate material 100 warps (the first surface S1) or the opposite surface (the second surface S2), as shown in FIG. 2, for example. In the example of FIG. 2, the label 110 is attached to the first surface S1 and includes a mark (WD) indicating that the surface to which the label is attached is the first surface S1 side. The substrate material from which a substrate that warps toward the first surface S1 side is cut out may be transported, stored, or used as an accommodated body accommodated in a container having a label indicating the position of the first surface S1 or the second surface S2. By confirming the position of the first surface S1 or the second surface S2 with reference to the label, the substrate material can be used easily and accurately in a desired orientation.

A substrate material in which the warpage direction of the substrate is controlled can be obtained, for example, by selecting a combination of a plurality of materials with different coefficients of thermal expansion so that the coefficient of thermal expansion changes in the thickness direction of the substrate material. Usually, if the coefficient of thermal expansion of the material forming the portion on the first surface S1 side is larger than the coefficient of thermal expansion of the material forming the portion on the second surface S2 side, the substrate tends to warp toward the first surface S1 side when heated.

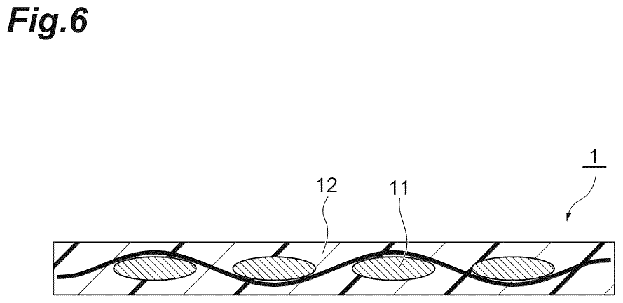

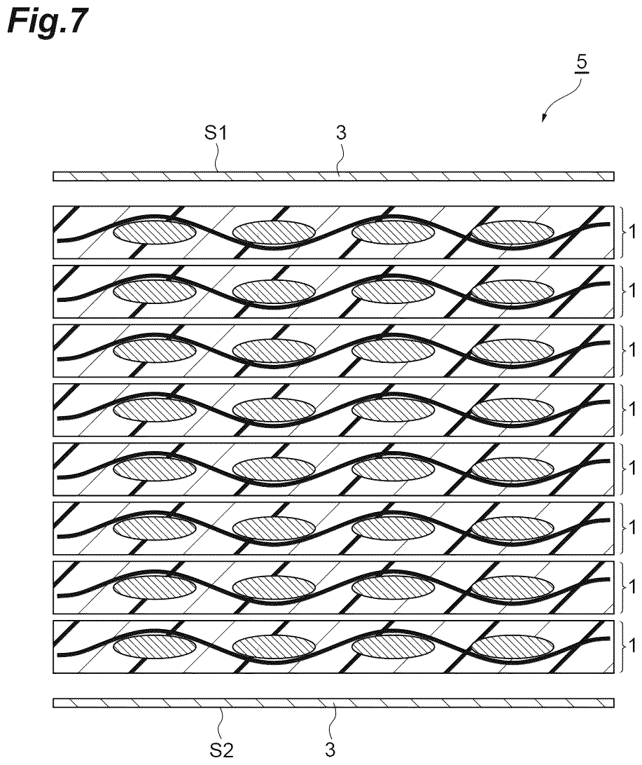

FIG. 6 is a cross-sectional view showing an example of a prepreg used for manufacturing a substrate material. FIG. 7 is a cross-sectional view showing an example of a method for manufacturing the substrate material 100 of FIG. 1 using prepregs. The method shown in FIG. 6 and FIG. 7 includes preparing a plurality of prepregs 1 including a sheet-like inorganic fibrous base material 11 and a thermosetting resin composition 12 impregnated in the inorganic fibrous base material 11, and forming an insulating substrate 10 by heating and pressing a laminate 5 including the plurality of prepregs 1. The laminate 5 shown in FIG. 7 further has two sheets of metal foil 3 arranged to sandwich the laminated plurality of prepregs 1 from both sides. By a molding process including raising the temperature of the laminated laminate 5 while pressing the laminate 5, the substrate material 100 is formed, which has the insulating substrate 10 formed by integrating two or more prepregs 1, and the metal foils 3 provided on both surfaces of the insulating substrate 10. An insulating resin layer may be provided between the metal foil 3 and the laminate 5. The thermosetting resin composition 12 is cured by heating the laminate 5 to form the insulating resin layer 12A of the substrate material 100.

By combining two or more kinds of prepregs 1 that exhibit different coefficients of thermal expansion after curing as the plurality of prepregs 1 constituting the laminate 5, the linear expansion coefficient of the substrate material can be varied in its thickness direction. The coefficient of thermal expansion of the prepreg 1 after curing can be adjusted by one or more factors selected from, for example, the type of the inorganic fibrous base material 11, the components contained in the thermosetting resin composition 12 and their content, and the content of the thermosetting resin composition 12 in the prepreg 1. For example, the order in which the prepregs 1 are laminated may be selected such that a prepreg 1 exhibiting a relatively large coefficient of thermal expansion after curing is arranged on the first surface S1 side, and a prepreg 1 exhibiting a relatively small coefficient of thermal expansion after curing is arranged on the second surface S2 side.

The inorganic fibrous base material 11 can be, for example, a woven or non-woven fabric including inorganic fibers. The inorganic fibers constituting the inorganic fibrous base material 11 may be glass fibers, carbon fibers, or a combination thereof. The inorganic fibrous base material 11 may be a glass cloth composed of glass fibers. The proportion of glass fibers among the inorganic fibers constituting the inorganic fibrous base material may be 80 to 100% by mass, 90 to 100% by mass, 95 to 100% by mass, or 99 to 100% by mass. The glass fibers may be, for example, E-glass, S-glass, or quartz glass. The thickness of the inorganic fibrous base material 11 may be 0.01 to 0.20 μm. When the coefficient of thermal expansion of the inorganic fibers constituting the inorganic fibrous base material 11 is large, the portion corresponding to the cured prepreg 1 in the substrate material 100 tends to exhibit a large coefficient of thermal expansion.

The thermosetting resin composition 12 includes a thermosetting resin component. The coefficient of thermal expansion after curing can be adjusted based on one or more of the type, content, and molecular weight of the components constituting the resin component. The thermosetting resin composition 12 may further include an inorganic filler. When the thermosetting resin composition 12 includes an inorganic filler, the portion of the thermosetting resin composition 12 excluding the inorganic filler may be regarded as the resin component.

The thermosetting resin component is a component that forms a cured product upon heating, and may include, for example, a thermosetting resin and a curing accelerator. The thermosetting resin is a compound that forms a cross-linked polymer upon heating, and usually has a reactive functional group that causes a cross-linking reaction. The reactive functional group may be, for example, an epoxy group, a hydroxyl group, a carboxyl group, an amino group, an amide group, an isocyanate group, an acryloyl group, a methacryloyl group, a vinyl group, a maleic anhydride group, or a combination thereof. The thermosetting resin may include an epoxy resin having two or more epoxy groups, an acrylate compound having two or more (meth)acryloyl groups, or a combination thereof. The content of the thermosetting resin may be, for example, 20 to 80% by mass, based on the total mass of the components other than the inorganic filler in the thermosetting resin composition 12.

The thermosetting resin may include a thermosetting elastomer having a reactive functional group. Examples of the thermosetting elastomer include styrene-based elastomers, olefin-based elastomers, urethane-based elastomers, polyester-based elastomers, polyamide-based elastomers, acrylic-based elastomers, and silicone-based elastomers. The content of the thermosetting elastomer may be, for example, 10 to 70% by mass, or 20 to 60% by mass, based on the total mass of the components other than the inorganic filler in the thermosetting resin composition.

Examples of the curing accelerator include peroxides, imidazole compounds, organophosphorus compounds, secondary amines, tertiary amines, and quaternary ammonium salts. These may be used singly or in combination of two or more. When the thermosetting resin is an epoxy resin, the curing accelerator may be, for example, an imidazole compound. The content of the curing accelerator may be, for example, 0.1 to 10% by mass, 0.5 to 5% by mass, or 0.75 to 3% by mass, based on the total mass of the components other than the inorganic filler in the thermosetting resin composition.

The thermosetting resin composition 12 may further include a thermoplastic resin as a resin component. The content of the thermoplastic resin may be, for example, 20 to 80% by mass, based on the total mass of the components other than the inorganic filler in the thermosetting resin composition 12.

The thermoplastic resin may be, for example, at least one selected from acrylic resins, polyamide resins, polyimide resins, and polyurethane resins. The thermoplastic resin may have a siloxane group. For example, an acrylic resin, a polyamide resin, a polyimide resin, or a polyurethane resin may have a siloxane group. The resin having a siloxane group may be a silicone resin. The polyimide resin having a siloxane group may be, for example, a polymer produced by a reaction between a siloxane diamine and a tetracarboxylic dianhydride, or a polymer produced by a reaction between a siloxane diamine and a bismaleimide.

The thermoplastic resin may have one or more reactive functional groups at a molecular terminal or in a molecular chain. Examples of the reactive functional group include an epoxy group, a hydroxyl group, a carboxyl group, an amino group, an amide group, an isocyanate group, an acryloyl group, a methacryloyl group, a vinyl group, and a maleic anhydride group.

The proportion of the thermosetting resin component in the thermosetting resin composition 12 may be 20% by mass or more, 30% by mass or more, or 40% by mass or more, and may be 100% by mass or less, or 80% by mass or less, with respect to the mass of the thermosetting resin composition 12. When the proportion of the resin component in the thermosetting resin composition 12 in the prepreg 1 is large, that is, the proportion of the inorganic filler is small, the coefficient of thermal expansion after curing tends to be large.

Examples of the inorganic filler include alumina, aluminum hydroxide, magnesium hydroxide, calcium carbonate, magnesium carbonate, calcium silicate, magnesium silicate, calcium oxide, magnesium oxide, aluminum oxide, aluminum nitride, crystalline silica, amorphous silica, boron nitride, titania, glass, iron oxide, ceramics, and carbon.

The content of the inorganic filler may be, for example, 40 to 300% by mass, based on the total mass of the components other than the inorganic filler in the thermosetting resin composition 12.

The average particle size of the inorganic filler may be 10 μm or less, or 5 μm or less, and may be 0.001 μm or more. The maximum particle size of the filler may be 30 μm or less, or 20 μm or less, and may be 0.001 μm or more. The average particle size and the maximum particle size of the inorganic filler can be, for example, the average value and the maximum value of the particle sizes, where the particle size is the maximum width in a two-dimensional image of the inorganic filler observed by a scanning electron microscope (SEM).

The thermosetting resin composition may further include other components as necessary. Examples of other components include adhesion promoters, silane coupling agents, triazole compounds, tetrazole compounds, ion scavengers, antioxidants, and organic fillers.

The content of the thermosetting resin composition 12 in the prepreg 1 may be 40 to 80% by mass, based on the mass of the prepreg 1. When the content of the thermosetting resin composition 12 in the prepreg 1 is large, the coefficient of thermal expansion after curing tends to increase.

The width of the prepreg 1 may be, for example, 200 to 1300 mm. The thickness of the prepreg 1 may be, for example, 15 to 300 μm. If the thickness of the prepreg 1 is less than 15 μm, the flatness of the substrate tends to be relatively reduced due to irregularities derived from the inorganic fibrous base material 11. If the thickness of the prepreg 1 is large, the warpage of the substrate tends to increase.

The prepreg 1 can be obtained, for example, by a method including impregnating the inorganic fibrous base material 11 with a resin varnish including the thermosetting resin composition 12 and a solvent, and removing the solvent from the resin varnish.

From the viewpoint of conductivity, the metal foil 3 may include copper, gold, silver, nickel, platinum, molybdenum, ruthenium, aluminum, tungsten, iron, titanium, chromium, or an alloy including at least one of these metal elements. The metal foil 3 may be a copper foil or an aluminum foil, and may be a copper foil. An insulating resin layer may be provided on the surface of the metal foil 3 on the prepreg 1 side.

The insulating substrate 10, and the substrate material 100 including it, may be formed by heating and pressing the laminate 5 under heating conditions in which an amount of heat applied to the laminate 5 from one surface side (first surface S1 side) of the laminate 5 and an amount of heat applied to the laminate 5 from the other surface side (second surface S2 side) of the laminate 5 are different. The heating conditions in this case may be determined such that the plurality of the sample substrates warp toward the first surface S1 side when heated. If the amount of heat applied is different, the amount of the thermosetting resin component remaining in the insulating resin layer 12A, which is a cured thermosetting resin composition, may change. When there is a difference in the amount of the resin component between the front and back surfaces of the substrate material, it tends to warp toward the side with a smaller amount of the remaining thermosetting resin component. The distribution of the remaining amount of the thermosetting resin component in the thickness direction in the insulating resin layer 12A can be detected, for example, by a method of identifying the type and proportion of constituent components from the position, height, and area of an exothermic peak observed by differential scanning calorimetry (DSC) measurement, or a method of identifying the type and proportion of constituent components from the analysis of an absorption spectrum by infrared spectroscopy (IR).

The heating conditions for forming the substrate material 100 may include raising the temperature of the laminate 5 to a molding temperature at a predetermined heating rate, and holding the temperature of the laminate 5 at the molding temperature. The molding temperature in this case may be, for example, 100 to 300 °C, or 150 to 250 °C. The time for heating and pressing at the molding temperature may be, for example, 0.1 to 5 hours.

While the laminate 5 is being heated, the laminate 5 is usually continuously pressed. The pressure applied to the laminate 5 may be, for example, 0.2 to 10 MPa.

The apparatus for heating and pressing the laminate 5 can be a hot press apparatus. The hot press apparatus may be, for example, a multi-stage press, a multi-stage vacuum press, a continuous molding machine, or an autoclave molding machine. When the apparatus for heating and pressing the laminate 5 is a hot press apparatus, a metal plate may be placed on the surface of the metal foil 3 opposite to the prepreg 1.

The wiring substrate for a semiconductor package can be obtained, for example, by a method including forming wiring on the metal foil 3 of the substrate 20 obtained from the substrate material 100 by a subtractive method, or by a method including forming wiring by a semi-additive method after removing the metal foil 3 if necessary. If necessary, a through-hole penetrating the insulating substrate 10 may be formed, and a conductive via filling the through-hole may be formed.

A build-up layer may be formed on the substrate 20 as a core material. In that case, wiring connected to a semiconductor chip can be formed on the build-up layer. The method for forming the build-up layer may be, for example, a subtractive method, a full additive method, a semi-additive process (SAP), a modified semi-additive process (m-SAP), or a trench method.

The trench method is a method including forming a build-up material or a photosensitive insulating material layer having a pattern including a groove portion on the substrate 20 as a core material, and filling the groove portion with a conductive material. The conductive material formed outside the groove portion is removed by a method such as CMP or fly-cutting.

A semiconductor package is manufactured by mounting an electronic component including a semiconductor chip at a predetermined position on a wiring substrate prepared using the substrate 20.

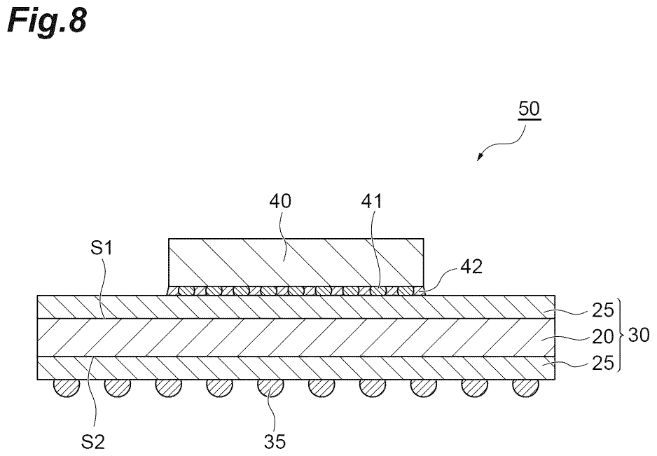

FIG. 8 is a cross-sectional view showing an example of a semiconductor package including a substrate obtained from a substrate material as a core material. A semiconductor package 50 shown in FIG. 8 has a wiring substrate 30, an electronic component 40 including a semiconductor chip mounted on the wiring substrate 30, and bumps 35 provided on the side of the wiring substrate 30 opposite to the electronic component 40. The wiring substrate 30 has a substrate 20 obtained from a substrate material and having a first surface S1 and a second surface S2, and build-up layers 25 including wiring provided on the first surface S1 side and the second surface S2 side of the substrate 20. On the first surface S1 side of the substrate 20, the electronic component 40 is flip-chip connected to the wiring substrate 30 by connection terminals 41. The space between the electronic component 40 (semiconductor chip) and the wiring substrate 30 may be filled with an underfill 42. The orientation of the substrate 20 in the semiconductor package 50 can be selected so that the warpage of the semiconductor package 50 after heating for reflow or the like is reduced.

### REFERENCE SIGNS LIST

1: prepreg, 5: laminate, 11: inorganic fibrous base material, 12: thermosetting resin composition, 20: substrate (sample substrate), 21: first substrate, 22: second substrate, 30: wiring substrate, 40: electronic component (semiconductor chip), 50: semiconductor package, 110: label, S1: first surface, S2: second surface.

1. A method for manufacturing a semiconductor package comprising:
cutting out, from a substrate material for semiconductor packages having a first surface and, on a reverse side thereof, a second surface, a plurality of substrates each having the first surface and the second surface;
classifying the plurality of cut-out substrates into first substrates that warp toward the first surface side when heated, and second substrates that warp toward the second surface side when heated; and
mounting an electronic component including a semiconductor chip on a surface on the first surface side of a wiring substrate including the first substrate, or on a surface on the second surface side of a wiring substrate including the second substrate.

2. A method for manufacturing a semiconductor package comprising:
cutting out, from a substrate material for semiconductor package having a first surface and, on a reverse side thereof, a second surface, a plurality of substrates each having the first surface and the second surface;
classifying the plurality of cut-out substrates into first substrates that warp toward the first surface side when heated, and second substrates that warp toward the second surface side when heated; and
mounting an electronic component including a semiconductor chip on a surface on the second surface side of a wiring substrate including the first substrate, or on a surface on the first surface side of a wiring substrate including the second substrate.

3. A substrate material for semiconductor packages having a first surface and, on a reverse side thereof, a second surface, wherein
a plurality of sample substrates, which are cut out from the substrate material for semiconductor packages and have the first surface and the second surface in a rectangular shape with a length of 60±1 mm and a width of 60±1 mm, warp toward the first surface side when heated.

4. The substrate material for semiconductor packages according to claim 3, wherein 90% or more of a set of at least ten sample substrates cut out from one sheet of the substrate material for semiconductor packages warp toward the first surface side when heated.

5. The substrate material for semiconductor packages according to claim 3, wherein the plurality of the sample substrates exhibit a maximum warpage amount of not less than 10 μm and not more than 350 μm when heated to 260 °C.

6. The substrate material for semiconductor packages according to claim 3, further comprising a label indicating a position of the first surface or the second surface of the substrate material for semiconductor packages.

7. The substrate material for semiconductor packages according to claim 3, wherein the substrate material for semiconductor packages comprises an insulating substrate formed by heating and pressing a laminate including a plurality of prepregs comprising an inorganic fibrous base material and a thermosetting resin composition impregnated in the inorganic fibrous base material.

8. The substrate material for semiconductor packages according to claim 7, wherein the laminate includes a combination of two or more kinds of the prepregs each comprising a different inorganic fibrous base material, and the two or more kinds of the prepregs are laminated in an order selected such that the plurality of the sample substrates warp toward the first surface side when heated.

9. The substrate material for semiconductor packages according to claim 7, wherein the laminate includes a combination of two or more kinds of the prepregs each comprising a different thermosetting resin composition, and the two or more kinds of the prepregs are laminated in an order selected such that the plurality of the sample substrates warp toward the first surface side when heated.

10. The substrate material for semiconductor packages according to claim 7, wherein
the insulating substrate is formed by heating and pressing the laminate under heating conditions in which an amount of heat applied to the laminate from one surface side of the laminate and an amount of heat applied to the laminate from the other surface side of the laminate are different, and
the heating conditions are determined such that the plurality of the sample substrates warp toward the first surface side when heated.

11. An accommodated body comprising:
the substrate material for semiconductor packages according to claim 3; and
a container accommodating the substrate material for semiconductor packages and having a label indicating a position of the first surface or the second surface of the substrate material for semiconductor packages.

12. A method for manufacturing the substrate material for semiconductor packages according to claim 7, comprising: forming an insulating substrate by heating and pressing a laminate including a plurality of prepregs comprising an inorganic fibrous base material and a thermosetting resin composition impregnated in the inorganic fibrous base material.

13. The method according to claim 12, wherein the laminate includes a combination of two or more kinds of the prepregs each comprising a different inorganic fibrous base material, and the two or more kinds of the prepregs are laminated in an order selected such that the plurality of the sample substrates warp toward the first surface side when heated.

14. The method according to claim 12, wherein the laminate includes a combination of two or more kinds of the prepregs each comprising a different thermosetting resin composition, and the two or more kinds of the prepregs are laminated in an order selected such that the plurality of the sample substrates warp toward the first surface side when heated.

15. The method according to claim 12, wherein
the insulating substrate is formed by heating and pressing the laminate under heating conditions in which an amount of heat applied to the laminate from one surface side of the laminate and an amount of heat applied to the laminate from the other surface side of the laminate are different, and
the heating conditions are determined such that the plurality of the sample substrates warp toward the first surface side when heated.
